(19) United States
(12) Patent Application Publication
(10) Pub. No.: US 2024/0313062 A1
(43) Pub. Date: Sep. 19, 2024

(54) Heterostructures and Processes Of Making and Using Same

(71) Applicant: Government of the United States, as represented by the Secretary of the Air Force, Wright-Patterson AFB, OH (US)

(72) Inventors: Nicholas R. Glavin, Springboro, OH (US); Michael Snure, Oakwood, OH (US); Eric W. Blanton, Dayton, OH (US)

(21) Appl. No.: 18/598,025

(22) Filed: Mar. 7, 2024

Related U.S. Application Data
(60) Provisional application No. 63/452,489, filed on Mar. 16, 2023.

(51) Int. Cl. H01L 29/205; H01L 29/20

(52) U.S. Cl. CPC H01L 29/205; H01L 29/2003

(57) ABSTRACT

The present invention relates to improved heterostructures and processes of making and using same. A peel and transfer process that disposes a first layer of boron nitride on said diamond substrate is provided. Such process yields heterostructures that having significantly improved mechanical and heat transfer properties. When such improved transistors and integrated circuits comprising such improved heterostructures are used in electronic devices, such devices are more efficient and can operate at higher frequencies.

### CROSS-REFERENCE TO RELATED APPLICATION

The present application claims priority to U.S. Provisional Application Ser. No. 63/452,489 filed Mar. 16, 2023, the contents of which is hereby incorporated by reference in their entry.

### RIGHTS OF THE GOVERNMENT

The invention described herein may be manufactured and used by or for the Government of the United States for all governmental purposes without the payment of any royalty.

### FIELD OF THE INVENTION

The present invention relates to improved heterostructures and processes of making and using same.

### BACKGROUND OF THE INVENTION

Transistors and integrated circuits comprise heterostructures that comprise a substrate layer on which other layers are disposed. It is particularly desirable to employ diamond as a substrate because diamond allows for improved heat transfer away from the transistor and integrated circuit. Unfortunately, it is particularly difficult to bond a layer on a diamond substrate as diamond is chemically inert and the surface of diamond substrates is typically rough and thus does not lend itself to bonding by Van der Waals force. As a result, heterostructures that comprise a substrate layer are general made by depositing an amorphous layer on the diamond substrate and then one or more layers is disposed on the amorphous layer and the overall heterostructure is annealed at temperature up to 500° C. Due to the annealing and composition of the amorphous layer, the overall heterostructure is weakened and the heat transfer capability of the heterostructure is compromised. Alternatively, the heterostructure can be produced by direct growth on a diamond substrate. However, direct growth processes cause defects in the layer(s) that are grown on the diamond substrate which in turn causes electron and/or phonon scattering. Such scattering significantly decreases transistor and integrated circuit efficiency and ability to operate at higher frequencies.

Applicants recognized that the source of the problem with producing heterostructures that comprise a diamond substrate layer was the overall combination of roughness, low thermal conductivity, poor chemical stability and conductivity of the material used as a first layer on said diamond substrate. Such recognition led Applicants to develop a peel and transfer process that disposes a first layer of boron nitride on said diamond substrate. Such process yields heterostructures having significantly improved mechanical and heat transfer properties. When such improved transistors and integrated circuits comprising such improved heterostructures are used in electronic devices, such devices are more efficient and can operate at higher frequencies.

### SUMMARY OF THE INVENTION

The present invention relates to improved heterostructures and processes of making and using same. A peel and transfer process that disposes a first layer of boron nitride on said diamond substrate is provided. Such process yields heterostructures that having significantly improved mechanical and heat transfer properties. When such improved transistors and integrated circuits comprising such improved heterostructures are used in electronic devices, such devices are more efficient and can operate at higher frequencies.

Additional objects, advantages, and novel features of the invention will be set forth in part in the description that follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is a schematic of a heterostructure stack comprising an aluminum-gallium nitride cap (1), gallium nitride layer (2), aluminum nitride layer (3), boron nitride layer (4) and on polycrystalline or single crystal diamond substrate (5).

FIG. 2 is cross-sectional STEM of the heterostructure stack comprising an aluminum-gallium nitride cap (1), gallium nitride layer (2), aluminum nitride layer (3), boron nitride layer (4) and on a sapphire substrate (5) prior to use and transfer to a diamond substrate.

FIG. 3 is a schematic showing the method of the prepared devices on the sapphire wafer followed by mechanical lift-off and subsequent bonding to a diamond substrate.

FIG. 4 is a schematic of a heterostructure stack comprising an aluminum-gallium nitride cap (1), gallium nitride layer (2), aluminum nitride layer (3), boron nitride layer (4), functionalized interfacial binder molecules (5) and a polycrystalline or single crystal diamond substrate (6).

### DETAILED DESCRIPTION OF THE INVENTION

### Definitions

Unless specifically stated otherwise, as used herein, the terms “a”, “an” and “the” mean “at least one”.

As used herein, the terms “include”, “includes” and “including” are meant to be non-limiting.

As used herein, the words “and/or” means, when referring to embodiments (for example an embodiment having elements A and/or B) that the embodiment may have element A alone, element B alone, or elements A and B taken together.

As used herein, the words “about,” “approximately,” or the like, when accompanying a numerical value, are to be construed as indicating a deviation as would be appreciated by one of ordinary skill in the art to operate satisfactorily for an intended purpose.

Unless otherwise noted, all component or composition levels are in reference to the active portion of that component or composition, and are exclusive of impurities, for example, residual solvents or by-products, which may be present in commercially available sources of such components or compositions.

All percentages and ratios are calculated by weight unless otherwise indicated. All percentages and ratios are calculated based on the total composition unless otherwise indicated.

It should be understood that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

### Gallium Nitride Films and Devices on Diamond Substrates Using Boron Nitride Interlayers

For purposes of this specification, headings are not considered paragraphs. Here, Applicants disclose a heterostructure comprising a diamond substrate, a boron nitride layer disposed on said diamond substrate and one or more tuning layers disposed on top of said boron nitride layer, said one or more tuning layers comprising at least one of Al, Ga, In, Sc, Zn and at least one of N, O, As, P.

Applicants disclose a heterostructure according to the previous paragraph, said heterostructure comprising a layer disposed between said boron nitride layer and said diamond substrate, preferably said layer between said boron nitride layer and said diamond substrate comprises aluminum oxide, hafnium oxide, indium oxide, titanium oxide, tungsten oxide, molybdenum oxide, silicon, carbon, oxygen, sulfur, hydroxyl groups, fluorine, chlorine, graphene and/or epoxy, more preferably said layer between said boron nitride layer and said diamond substrate comprises aluminum oxide, hafnium oxide, indium oxide, titanium oxide, tungsten oxide, molybdenum oxide, silicon, carbon, oxygen, sulfur, hydroxyl groups and/or fluorine, most preferably said layer between said boron nitride layer and said diamond substrate comprises aluminum oxide, hafnium oxide, indium oxide, silicon carbon, oxygen, sulfur, hydroxyl groups and/or fluorine.

Applicants disclose a heterostructure according to any of the previous two paragraphs, wherein said boron nitride layer and/or said diamond substrate are functionalized, said functionalization present on the surface of the surface boron nitride layer in contact with said diamond substrate and/or on the surface of the diamond substrate in contact with said boron nitride layer.

Applicants disclose a heterostructure according to any of the previous three paragraphs, wherein said one or more tuning layers disposed on top of said boron nitride layer comprises at least one of AlN; GaN; InN; ScN; Al₁₋ₓGaₓN wherein x is a number between 0 and 1; Al₁₋ₓInₓN wherein x is a number between 0 and 1; Al₁₋ₓScₓN wherein x is a number between 0 and 1; Ga₁₋ₓInₓN wherein x is a number between 0 and 1; Ga₁₋ₓScₓN wherein x is a number between 0 and 1; In₁₋ₓScₓN wherein x is a number between 0 and 1; Al_{1-x-y}GaₓIn_{y}N wherein x is a number between 0 and 1, wherein y is a number between 0 and 1 with the proviso that the sum of x and y is less than 1; Al_{1-x-y}GaₓSc_{y}N wherein x is a number between 0 and 1, wherein y is a number between 0 and 1 with the proviso that the sum of x and y is less than 1; Al_{1-x-y}InₓSc_{y}N wherein x is a number between 0 and 1, wherein y is a number between 0 and 1 with the proviso that the sum of x and y is less than 1; Ga_{1-x-y}InₓSc_{y}N wherein x is a number between 0 and 1, wherein y is a number 0 and 1 with the proviso that the sum of x and y is less than 1; Ga_{1-x-y}InₓSc_{y}N wherein x is a number between 0 and 1, wherein y is a number between 0 and 1 with the proviso that the sum of x and y is less than 1; GaAs; AlAs; InAs; Al₁₋ₓGaₓAs wherein x is a number between 0 and 1; Al₁₋ₓInₓAs wherein x is a number between 0 and 1, Ga₁₋ₓInₓA wherein x is a number between 0 and 1; Al_{1-x-y}GaₓIn_{y}As wherein x is a number between 0 and 1, wherein y is a number between 0 and 1 with the proviso that the sum of x and y is less than 1; AlP; GaP; InP; Al₁₋ₓGaₓP wherein x is a number between 0 and 1; Al₁₋ₓInₓP wherein x is a number between 0 and 1; Ga₁₋ₓInₓP wherein x is a number between 0 and 1; Al_{1-x-y}GaₓIn_{y}P wherein x is a number between 0 and 1, wherein y is a number between 0 and 1 with the proviso that the sum of x and y is less than 1; GaAs_{1-z}P_{z} wherein z is a number between 0 and 1; AlAs_{1-z}P_{z} wherein z is a number between 0 and 1; InAs_{1-z}P_{z} wherein z is a number between 0 and 1; Al₁₋ₓInₓAs_{1-z}P_{z} wherein x is a number between 0 and 1, wherein z is a number between 0 and 1; Al₁₋ₓGaₓAs_{1-z}P_{z} wherein x is a number between 0 and 1, wherein z is a number between 0 and 1; Ga₁₋ₓInₓAs_{1-z}P_{z} wherein x is a number between 0 and 1, wherein z is a number between 0 and 1; Al_{1-x-y}GaₓIn_{y}As_{1-z}P_{z} wherein z is a number between 0 and 1, x is a number between 0 and 1, wherein y is a number between 0 and 1 with the proviso that the sum of x and y is less than 1; ZnO; Ga₂O₃; or Ga₂₋ₓAlₓO₃ x is a number between 0 and 2.

Applicants disclose a heterostructure according to any of the previous four paragraphs, wherein said diamond substrate is nanocrystalline, polycrystalline, or single crystalline.

Applicants disclose a heterostructure according to any of the previous five paragraphs, wherein said diamond substrate comprises a dopant, preferably said diamond substrate comprises, based on the sum of the atomic composition of said diamond substrate and said dopant, from about 1×10⁻¹² atomic % to about 10 atomic % of a dopant, more preferably said diamond substrate comprises, based on the sum of the atomic composition of said diamond substrate and said dopant, from about 1×10⁻⁶ atomic % to about 5 atomic % of a dopant, more preferably said diamond substrate comprises, based on the sum of the atomic composition of said diamond substrate and said dopant, from about 1×10⁻⁶ atomic % to about 2 atomic % of a dopant.

Applicants disclose a heterostructure according to the previous paragraph, wherein said dopant is selected from hydrogen, boron, oxygen, lithium, sodium, nitrogen, phosphorous, arsenic, silicon, germanium, carbon, iron, zinc, magnesium and mixtures thereof; preferably said dopant is selected from oxygen, hydrogen, boron, silicon, germanium, carbon, iron, zinc, magnesium, phosphorous and mixtures thereof; more preferably said dopant is selected from oxygen, boron, silicon, germanium, carbon, iron, zinc, magnesium, phosphorous and mixtures thereof; most preferably said dopant is selected from boron, phosphorous and mixtures thereof.

Applicants disclose a heterostructure according to any of the previous six paragraphs, said heterostructure comprising from 1 to about one thousand tuning layers, preferably said heterostructure comprises from 1 to about 100 tuning layers, more preferably said heterostructure comprises from 1 to about 20 tuning layers, most preferably said heterostructure comprises from 1 to about 10 tuning layers.

Applicants disclose a heterostructure according to any of the previous seven paragraphs, wherein; said diamond substrate has a thickness of from about 50 micrometers to about 10 millimeters, more preferably from about 100 micrometers to about 5 millimeter, most preferably from about 500 micrometers to about 2 millimeters; said boron nitride layer has a thickness of from about 0.2 nanometer to about 1000 nanometer, more preferably from about 1 nanometer to about 100 nanometers, most preferably from about 1.5 nanometers to about 10 nanometers; and said one or more tuning layers have a thickness of from about 0.1 nanometer to about 1 millimeter, more preferably from about 1 nanometer to about 100 micrometers, most preferably from about 1 nanometer to about 5 micrometers.

Applicants disclose a heterostructure according to any of the previous eight paragraphs, said heterostructure comprising: a first tuning layer comprising from about 10 nanometers to about 100 micrometers of GaN, preferably from about 100 nanometers to about 10 micrometers of GaN, more preferably from about 500 nanometers to about 5 micrometers of GaN, most preferably from about 1 micrometers to about 2 micrometers of GaN, said first tuning layer being disposed on said boron nitride layer; a first tuning layer comprising from about 0.2 nanometers to about 2 micrometers of AlN, preferably from about 1 nanometers to about 100 nanometers of AlN, more preferably from about 2 nanometers to about 50 nanometers of AlN, most preferably from about 5 nanometers to about 30 nanometers of AlN, said first tuning layer being disposed on said boron nitride layer, a second tuning layer comprising from about 10 nanometers to about 100 micrometers of GaN, preferably from about 100 nanometers to about 10 micrometers of GaN, more preferably from about 500 nanometers to about 5 micrometers of GaN, most preferably from about 1 micrometers to about 2 micrometers of GaN, said second tuning layer being disposed on said first tuning layer; a first tuning layer comprising from about 0.2 nanometers to about 2 micrometers of AlN, preferably from about 1 nanometers to about 100 nanometers of AlN, more preferably from about 2 nanometers to about 50 nanometers of AlN, most preferably from about 5 nanometers to about 30 nanometers of AlN, said first tuning layer being disposed on said boron nitride layer, a second tuning layer comprising from about 10 nanometers to about 100 micrometers of GaN, preferably from about 100 nanometers to about 10 micrometers of GaN, more preferably from about 500 nanometers to about 5 micrometers of GaN, most preferably from about 1 micrometers to about 2 micrometers of GaN, said second tuning layer being disposed on said first tuning layer; a third tuning layer comprising of about 0.2 nanometers to about 50 nanometers of AlN, preferably from about 0.3 nanometers to about 30 nanometers of AlN, more preferably from about 0.4 nanometers to about 10 nanometers of AlN, most preferably from about 0.5 nanometers to about 3 nanometers of AlN, said third tuning layer being disposed on said second tuning layer, a fourth tuning layer comprising from about 1 nanometers to about 100 nanometers of Al_{0.27}Ga_{0.73}N, preferably from about 2 nanometers to about 50 nanometers of Al_{0.27}Ga_{0.73}N, more preferably from about 4 nanometers to about 40 nanometers of Al_{0.27}Ga_{0.73}N, most preferably from about 5 nanometers to about 30 nanometers of Al_{0.27}Ga_{0.73}N, 20 nanometers of Al_{0.27}Ga_{0.73}N, said forth tuning layer being disposed on said third tuning layer, a fifth tuning layer comprising from about 0.1 nanometers to about 100 nanometers of GaN, preferably from about 0.3 nanometers to about 20 nanometers of GaN, more preferably from about 0.5 nanometers to about 10 nanometers of GaN, most preferably from about 1 nanometer to about 5 nanometers GaN, said fifth tuning layer being disposed on said fourth tuning layer; a first tuning layer comprising from about 0.2 nanometers to about 2 micrometers of AlN, preferably from about 1 nanometers to about 100 nanometers of AlN, more preferably from about 2 nanometers to about 50 nanometers of AlN, most preferably from about 5 nanometers to about 30 nanometers of AlN, said first tuning layer being disposed on said boron nitride layer, a second tuning layer comprising from about 10 nanometers to about 100 micrometers of GaN, preferably from about 100 nanometers to about 10 micrometers of GaN, more preferably from about 500 nanometers to about 5 micrometers of GaN, most preferably from about 1 micrometers to about 2 micrometers of GaN, said second tuning layer being disposed on said first tuning layer; a third tuning layer comprising of about 0.2 nanometers to about 50 nanometers of AlN, preferably from about 0.3 nanometers to about 30 nanometers of AlN, more preferably from about 0.4 nanometers to about 10 nanometers of AlN, most preferably from about 0.5 nanometers to about 3 nanometers of AlN, said third tuning layer being disposed on said second tuning layer, a fourth tuning layer comprising from about 1 nanometers to about 100 nanometers of Al_{0.2}Sc_{0.8}N, preferably from about 2 nanometers to about 50 nanometers of Al_{0.2}Sc_{0.8}N, more preferably from about 4 nanometers to about 40 nanometers of Al_{0.2}Sc_{0.8}N, most preferably from about 5 nanometers to about 30 nanometers of Al_{0.2}Sc_{0.8}N, 20 nanometers of Al_{0.2}Sc_{0.8}N, said fourth tuning layer being disposed on said third tuning layer, a fifth tuning layer comprising of about 0.1 nanometers to about 100 nanometers of GaN, preferably from about 0.3 nanometers to about 20 nanometers of GaN, more preferably from about 0.5 nanometers to about 10 nanometers of GaN, most preferably from about 1 nanometer to about 5 nanometers GaN, said fifth tuning layer being disposed on said fourth tuning layer; or a first tuning layer comprising from about 0.2 nanometers to about 100 micrometers of Ga₂O₃, preferably from about 1 nanometers to about 50 micrometers of Ga₂O₃, more preferably from about 2 nanometers to about 10 micrometers of Ga₂O₃, most preferably from about 10 nanometers to about 5 micrometers of Ga₂O₃, said first tuning layer being disposed on said boron nitride layer.

Applicants disclose a heterostructure according to any of the previous nine paragraphs, wherein at least one of said one or more tuning layers comprises a dopant, preferably each of said one or more tuning layers independently comprises, based on the sum of the atomic composition of said one or more tuning layers and said dopant, from about 1×10⁻¹² atomic % to about 10 atomic % of said dopant, more preferably each of said one or more tuning layers independently comprises, based on the sum of the atomic composition of said one or more tuning layers and said dopant, from about 1×10⁻⁶ atomic % to about 5 atomic % of said dopant, most preferably each of said one or more tuning layers independently comprises, based on the sum of the atomic composition of said one or more tuning layers and said dopant, from about 1×10⁻⁶ atomic % to about 2 atomic % of said dopant.

Applicants disclose a heterostructure according to any of the previous paragraph wherein said dopant is selected from hydrogen, oxygen, boron, aluminum, gallium, indium, phosphorous, arsenic, antimony, bismuth, lithium, germanium, silicon, nitrogen, gold, platinum, tellurium, sulfur, selenium, iron, tin, germanium, beryllium, zinc, chromium, carbon, magnesium, chlorine, fluorine, sodium, aluminum and mixtures thereof; preferably said dopant is selected from hydrogen, oxygen, boron, aluminum, gallium, indium, phosphorous, arsenic, antimony, bismuth, lithium, germanium, silicon, nitrogen, tellurium, sulfur, selenium, iron, tin, germanium, zinc, chromium, carbon, magnesium, chlorine, fluorine, sodium, aluminum and mixtures thereof; more preferably said dopant is selected from hydrogen, oxygen, boron, aluminum, gallium, indium, phosphorous, arsenic, antimony, bismuth, lithium, germanium, silicon, nitrogen, tellurium, sulfur, selenium, iron, tin, germanium, zinc, chromium, carbon, magnesium, sodium, aluminum and mixtures thereof; most preferably said dopant is selected from silicon, germanium, carbon, magnesium, iron, sulfur, tellurium, sulfur, selenium, and mixtures thereof.

Applicants disclose a heterostructure according to any of the previous eleven paragraphs, said heterostructure comprising a device structure disposed on top of the last tuning layer comprising ohmic metal contacts, metal gate contacts, dielectric gate layers, dielectric passivation layers, metal field plates, metal insulator metal capacitors, metal insulator semiconductor capacitors, and/or metal interconnects.

Applicants disclose an electronic component comprising a heterostructure according to any of the previous twelve paragraphs, preferably said electronic component is a high electron mobility transistor, transistor, or diode.

Applicants disclose an electronic device comprising an electronic component according to the previous paragraph, preferably said electronic component is a power amplifier, light emitting diode or integrated circuit.

Applicants disclose a platform comprising the electronic device of the previous paragraph, preferably said platform is a radar, transmitter, or communication system.

### Process of Making

For purposes of this specification, headings are not considered paragraphs. Here, Applicants disclose a process of making a heterostructure comprising a film, comprising a top layer and a bottom layer, said top layer comprising one or more tuning layers said bottom layer comprising a boron nitride layer, and a diamond substrate having a top and a bottom, said process comprising disposing the bottom of said film on to said top of said diamond substrate.

Applicants disclose a process of making a heterostructure according to the previous paragraph wherein said bottom of said film and/or top of said diamond substrate are functionalized prior to disposing the bottom of said film on to said top of said diamond substrate, preferably said functionalization comprises direct van der Waals bonding, covalent bonding, chemical treatment, surface roughening, plasma treatment, atomic layer deposition, chemical vapor deposition, physical vapor deposition, or thermal treatment.

Systems for MOCVD growth of h-BN can be obtained from Agnitron Technology (8360 Commerce Dr., Chanhassen, MN 55317) or Aixtron SE (1700 Wyatt Drive, Suite 14-15, Santa Clara, CA 95054). Suitable precursors for h-BN synthesis can be obtained from EMD performance materials, DockWeiler Chemical and Stem Chemicals.

### Examples

The following examples illustrate particular properties and advantages of some of the embodiments of the present invention. Furthermore, these are examples of reduction to practice of the present invention and confirmation that the principles described in the present invention are therefore valid but should not be construed as in any way limiting the scope of the invention.

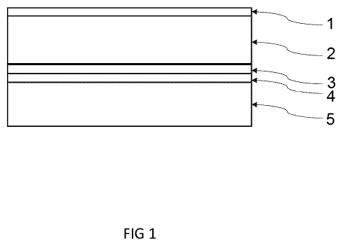

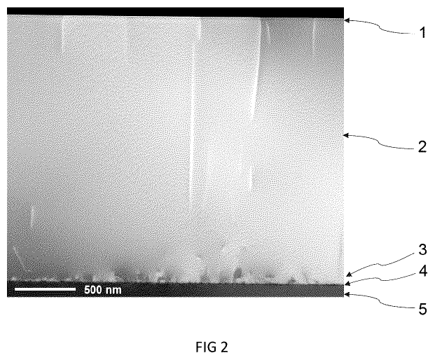

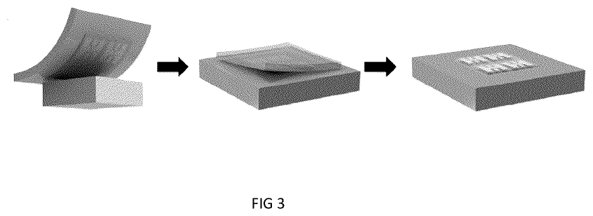

Example 1: Gallium Nitride HEMT attached to a diamond wafer through van der Waals bonding. Boron nitride films were deposited by low pressure MOCVD on sapphire at 1000° C. from triethylboron and NH3 with a V/III ratio of 2250 and pressure of 20 Torr. BN/sapphire templates were then loaded into an EMCORE D180 MOCVD system for growth of AlGaN/GaN (HEMT) structures. Ammonia, trimethylaluminum, trimethylgallium, and ferrocene were used as N, Al, Ga, and Fe precursors. A 15 nm thick AlN nucleation layer was deposited at 1000° C. using a V/III ratio of 2300 followed by a three step process for high temperature (1025° C.) growth of a 1.5 μm Fe doped GaN, 0.5 μm undoped GaN layer, 2 nm AlN insert layer, 17 nm AlGaN boundary layer with 27% Al, and 3 nm GaN cap layer. A cross-sectional image of the structure is shown in FIG. 2. Devices are then fabricated on top of the structure (FIG. 3). Immediately following, a thermal release tape is applied to the surface and the devices are cleaved from the substrate, separating at the h-BN/sapphire interface. Then, the devices are stamped onto a diamond wafer and the thermal release tape is removed via heating the structure, leaving a GaN HEMT device stack on diamond with an h-BN interlayer (FIG. 1).

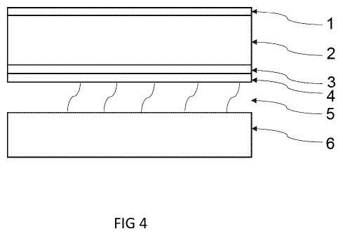

Example 2: h-BN membrane is functionalized with OH molecules for improved thermal bonding to diamond. Upon removing the GaN/AlN/h-BN heterostructure from the growth sapphire wafer, the h-BN is functionalized and/or decorated with OH molecules (such as shown in FIG. 4). A diamond wafer is then terminated with hydrogen molecules (H), encouraging a covalent bond to the h-BN/diamond interface and improving the thermal properties at the junction.

Every document cited herein, including any cross referenced or related patent or application and any patent application or patent to which this application claims priority or benefit thereof, is hereby incorporated herein by reference in its entirety unless expressly excluded or otherwise limited. The citation of any document is not an admission that it is prior art with respect to any invention disclosed or claimed herein or that it alone, or in any combination with any other reference or references, teaches, suggests or discloses any such invention. Further, to the extent that any meaning or definition of a term in this document conflicts with any meaning or definition of the same term in a document incorporated by reference, the meaning or definition assigned to that term in this document shall govern.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and process, and illustrative examples shown and described. Accordingly, departures may be made from such details without departing from the scope of the general inventive concept.

What is claimed is:

1. A heterostructure comprising a diamond substrate, a boron nitride layer disposed on said diamond substrate and one or more tuning layers disposed on top of said boron nitride layer, said one or more tuning layers comprising at least one of Al, Ga, In, Sc, Zn and at least one of N, O, As, P.

2. The heterostructure of claim 1 comprising a layer disposed between said boron nitride layer and said diamond substrate.

3. The heterostructure of claim 1 comprising a layer disposed between said boron nitride layer and said diamond substrate, said layer between said boron nitride layer and said diamond substrate comprising aluminum oxide, hafnium oxide, indium oxide, titanium oxide, tungsten oxide, molybdenum oxide, silicon, carbon, oxygen, sulfur, hydroxyl groups, fluorine, chlorine, graphene, and/or epoxy.

4. The heterostructure of claim 1 comprising a layer disposed between said boron nitride layer and said diamond substrate, said layer between said boron nitride layer and said diamond substrate comprising aluminum oxide, hafnium oxide, indium oxide, titanium oxide, tungsten oxide, molybdenum oxide, silicon, carbon, oxygen, sulfur, hydroxyl groups and/or fluorine.

5. The heterostructure of claim 1 comprising a layer disposed between said boron nitride layer and said diamond substrate, said layer between said boron nitride layer and said diamond substrate comprising aluminum oxide, hafnium oxide, indium oxide, silicon carbon, oxygen, sulfur, hydroxyl groups and/or fluorine.

6. The heterostructure of claim 1 wherein said boron nitride layer and/or said diamond substrate are functionalized, said functionalization present on the surface of the surface boron nitride layer in contact with said diamond substrate and/or on the surface of the diamond substrate in contact with said boron nitride layer.

7. The heterostructure of claim 1 wherein said one or more tuning layers disposed on top of said boron nitride layer comprises at least one of:
a) AlN;
b) GaN;
c) InN;
d) ScN;
e) Al₁₋ₓGaₓN wherein x is a number between 0 and 1;
f) Al₁₋ₓInₓN wherein x is a number between 0 and 1;
g) Al₁₋ₓScₓN wherein x is a number between 0 and 1;
h) Ga₁₋ₓInₓN wherein x is a number between 0 and 1;
i) Ga₁₋ₓScₓN wherein x is a number between 0 and 1;
j) In₁₋ₓScₓN wherein x is a number between 0 and 1;
k) Al_{1-x-y}GaₓIn_{y}N wherein x is a number between 0 and 1, wherein y is a number between 0 and 1 with the proviso that the sum of x and y is less than 1;
l) Al_{1-x-y}GaₓSc_{y}N wherein x is a number between 0 and 1, wherein y is a number between 0 and 1 with the proviso that the sum of x and y is less than 1;
m) Al_{1-x-y}InₓSc_{y}N wherein x is a number between 0 and 1, wherein y is a number between 0 and 1 with the proviso that the sum of x and y is less than 1;
n) Ga_{1-x-y}InₓSc_{y}N wherein x is a number between 0 and 1, wherein y is a number 0 and 1 with the proviso that the sum of x and y is less than 1;
o) Ga_{1-x-y}InₓSc_{y}N wherein x is a number between 0 and 1, wherein y is a number between 0 and 1 with the proviso that the sum of x and y is less than 1;
p) GaAs;
q) AlAs;
r) InAs;
s) Al₁₋ₓGaₓAs wherein x is a number between 0 and 1;
t) Al₁₋ₓInₓAs wherein x is a number between 0 and 1,
u) Ga₁₋ₓInₓA wherein x is a number between 0 and 1;
v) Al_{1-x-y}GaₓIn_{y}As wherein x is a number between 0 and 1, wherein y is a number between 0 and 1 with the proviso that the sum of x and y is less than 1;
w) AlP;
x) GaP;
y) InP;
z) Al₁₋ₓGaₓP wherein x is a number between 0 and 1;
aa) Al₁₋ₓInₓP wherein x is a number between 0 and 1;
bb) Ga₁₋ₓInₓP wherein x is a number between 0 and 1;
cc) Al_{1-x-y}GaₓIn_{y}P wherein x is a number between 0 and 1, wherein y is a number between 0 and 1 with the proviso that the sum of x and y is less than 1;
dd) GaAs_{1-z}P_{z} wherein z is a number between 0 and 1;
ee) AlAs_{1-z}P_{z} wherein z is a number between 0 and 1;
ff) InAs_{1-z}P_{z} wherein z is a number between 0 and 1;
gg) Al₁₋ₓInₓAs_{1-z}P_{z} wherein x is a number between 0 and 1, wherein z is a number between 0 and 1;
hh) Al₁₋ₓGaₓAs_{1-z}P_{z} wherein x is a number between 0 and 1, wherein z is a number between 0 and 1;
ii) Ga₁₋ₓInₓAs_{1-z}P_{z} wherein x is a number between 0 and 1, wherein z is a number between 0 and 1;
jj) Al_{1-x-y}GaₓIn_{y}As_{1-z}P_{z} wherein z is a number between 0 and 1, x is a number between 0 and 1, wherein y is a number between 0 and 1 with the proviso that the sum of x and y is less than 1;
ll) ZnO;
mm) Ga₂O₃; or
nn) Ga₂₋ₓAlₓO₃ x is a number between 0 and 2.

8. The heterostructure of claim 1 wherein said diamond substrate is nanocrystalline, polycrystalline, or single crystalline.

9. The heterostructure of claim 1 wherein said diamond substrate comprises a dopant.

10. The heterostructure of claim 9 wherein said diamond substrate comprises, based on the sum of the atomic composition of said diamond substrate and said dopant, from about 1×10⁻¹² atomic % to about 10 atomic % dopant.

11. The heterostructure of claim 10 wherein said diamond substrate comprises, based on the sum of the atomic composition of said diamond substrate and said dopant, from about 1×10⁻⁶ atomic % to about 5 atomic % dopant.

12. The heterostructure of claim 11 wherein said diamond substrate comprises, based on the sum of the atomic composition of said diamond substrate and said dopant, from about 1×10⁻⁶ atomic % to about 2 atomic % dopant.

13. The heterostructure of claim 9 wherein said dopant is selected from hydrogen, boron, oxygen, lithium, sodium, nitrogen, phosphorous, arsenic, silicon, germanium, carbon, iron, zinc, magnesium and mixtures thereof.

14. The heterostructure of claim 13 wherein said dopant is selected from oxygen, hydrogen, boron, silicon, germanium, carbon, iron, zinc, magnesium, phosphorous and mixtures thereof.

15. The heterostructure of claim 14 wherein said dopant is selected from oxygen, boron, silicon, germanium, carbon, iron, zinc, magnesium, phosphorous and mixtures thereof.

16. The heterostructure of claim 6 wherein said dopant is selected from boron, phosphorous and mixtures thereof.

17. The heterostructure of claim 1 comprising from 1 to about one thousand tuning layers.

18. The heterostructure of claim 17 comprising from 1 to about 100 tuning layers.

19. The heterostructure of claim 18 comprising from 1 to about 20 tuning layers.

20. The heterostructure of claim 19 comprising from 1 to about 10 tuning layers.

21. The heterostructure of claim 1 wherein;
a.) said diamond substrate has a thickness of from about 50 micrometers to about 10 millimeters;
b.) said boron nitride layer has a thickness of from about 0.2 nanometer to about 1000 nanometer; and
c.) said one or more tuning layers have a thickness of from about 0.1 nanometer to about 1 millimeter.

22. The heterostructure of claim 21 wherein;
a.) said diamond substrate has a thickness of from about 100 micrometers to about 5 millimeters;
b.) said boron nitride layer has a thickness of from about 1 nanometer to about 100 nanometers; and
c.) said one or more tuning layers have a thickness of from about 1 nanometer to about 100 micrometers.

23. The heterostructure of claim 22 wherein;
a.) said diamond substrate has a thickness of from about 500 micrometers to about 2 millimeters;
b.) said boron nitride layer has a thickness of from about 1.5 nanometers to about 10 nanometers; and
c.) said one or more tuning layers have a thickness of from about 1 nanometer to about 5 micrometers.

24. The heterostructure of claim 1 comprising a device structure disposed on top of the last tuning layer comprising ohmic metal contacts, metal gate contacts, dielectric gate layers, dielectric passivation layers, metal field plates, metal insulator metal capacitors, metal insulator semiconductor capacitors, and/or metal interconnects.

25. An electronic component comprising a heterostructure according to claim 1.

26. The electronic component according to claim 25, said electronic component being a high electron mobility transistor, transistor, or diode.

27. An electronic device comprising an electronic component according to claim 25.

28. The electronic device of claim 27, said electronic device being a power amplifier, light emitting diode or integrated circuit.

29. A platform comprising the electronic device of claim 27.

30. The platform of claim 29, said platform being a radar, transmitter, or communication system.
